(19) United States
(12) Patent Application Publication
(10) Pub. No.: US 2022/0085309 A1
(43) Pub. Date: Mar. 17, 2022

(54) ORGANIC ELECTROCHEMICAL TRANSISTOR HAVING AN IMPROVED CONDUCTIVE CHANNEL

(71) Applicants: VALOTEC, Villejuif (FR); UNIVERSITÉ DE PARIS, Paris (FR); CENTRE NATIONAL DE LA RECHERCHE SCIENTIFIQUE, Paris (FR)

(72) Inventors: Dany CAPITAO, Villejuif (FR); Antoine MAURIN, Villejuif (FR); Vincent NOËL, Paris Cedex 13 (FR); Giorgio MATTANA, Paris Cedex 13 (FR); Benoît PIRO, Paris Cedex 13 (FR); Caroline ABREU, Paris Cedex 13 (FR)

(73) Assignees: VALOTEC, Villejuif (FR); UNIVERSITÉ DE PARIS, Paris (FR); CENTRE NATIONAL DE LA RECHERCHE SCIENTIFIQUE, Paris (FR)

(21) Appl. No.: 17/414,091

(22) PCT Filed: Dec. 19, 2019
(86) PCT No.: PCT/EP2019/086171

§ 371 Date: Jun. 15, 2021

(30) Foreign Application Priority Data
Dec. 19, 2018 (EP) 18306742.0

(51) Int. Cl. H01L 51/05; G01N 27/414; H01L 51/10; H01L 51/00

(52) U.S. Cl. CPC H01L 51/0558; G01N 27/4146; H01L 51/0043; H01L 51/0036; H01L 51/102

(57) ABSTRACT

An organic electrochemical device including a substrate on which a source and drain are located, a gate electrode, and either a conductive channel of at least one organic conductive track or a conductive channel including at least one organic conductive track. Also, a method of manufacturing the organic electrochemical device.

### FIELD OF INVENTION

The present invention relates to the field of electrochemical devices. Especially, the present invention relates to an organic electrochemical transistor device (OECT) with a conductive channel comprising at least one organic conductive track having a specific shape for improving the charge carriers mobility inside said OECT.

### BACKGROUND OF INVENTION

During the past two decades, organic semi-conductors have attracted a great deal of attention due to potential applications in a variety of electronic technologies.

Among organic semi-conductors-based devices, the organic electrochemical transistors (OECTs) are of great interest due to their use as transducers in lab-on chip platforms for biomedical applications. OECTs use an electrolyte as an integral part of their device structure, this latter comprising a gate electrode and a polymer conductive channel disposed between a drain and a source electrode.

Today, there is a need for providing more sophisticated electrochemical devices for biomedical applications that include increased number of fluidic, electronic and/or mechanical components.

Conventional OECT manufacturing techniques involve a succession of thin film deposits requiring vacuum processes and photolithography including spin coating, UV exposures, developments and etchings. These methods require multiple levels of masks and involve significant waste increasing the price of the process.
L. Basirico et al. “Electrical Characteristics of ink-jet printed, all polymer electrochemical transistors”, Organic Electronics, Vol. 13, no. 2; 2 Dec. 2011, pp 244-248 discloses conventional OECT with large and unique conductive channels, limiting sensitivity of the device.
Mahiar Hamedi et al. “Electrochemical devices made from conducting nanowire networks self-assembled from amyloid fibrils and alkoxysulfonate PEDOT”, Nano Letters, Vol. 8, no. 6, 5 Sep. 2008, pp 1736-1740—ISSN:1530-6984—DOI:10.1021/n10808233 discloses conductive modified amyloid nanofibrils whose conductivity is demonstrated with a field effect transistor set-up in which nanofibrils are used as conductive channels and limited to very low intensity/signal. Thus, there is a need for providing OECT manufacturing processes that are more versatile and less expensive. Especially, there is a need for providing optimized organic electrochemical transistors, having improved electrical performances such as for example a better sensitivity.

Surprisingly, the Applicant evidences that a specific design of the conductive channel, preferably obtained by ink-jet printing, provides an organic electrochemical transistor in which the distance to be covered by the ions, from the electrolyte into the conductive channel, is decreased and allows achieving a lower response time and so far a faster switch between the “on” state and the “off” state of the channel

### SUMMARY

Thus, this invention relates to an organic electrochemical transistor (OECT) comprising:
a substrate on which are located a source and a drain;
a gate electrode; and
a conductive channel located on the substrate and contacting on one of its ends the source and on its other end the drain, said conductive channel comprising or consisting of at least one organic conductive track;
wherein said at least one organic conductive track is characterized by:
a contact surface (S_{contact}) corresponding to the contact surface of the at least one organic conductive track (51) with an electrolyte solution;
a projected surface (S_{projected}) corresponding to the contact surface of the at least one organic conductive track with the substrate; said projected surface (S_{projected}) ranging from 10⁻⁴ cm² to 0.05 cm² or said projected surface (S_{projected}) being the contact surface of multiple organic conductive tracks, each of said multiple organic conductive tracks having a width w ranging from 1 μm to 200 μm; and
a ratio R between the contact surface S_{contact} and the projected surface S_{projected} higher than 1.

According to one embodiment, the ratio r of the width w by height h of the at least one organic conductive track ranges from 1 to 200.

According to one embodiment, the ratio R ranges from 1 to 4.

According to one embodiment, the conductive channel comprises or consists of at least two organic conductive tracks, preferably from 2 to 50 organic conductive tracks, more preferably from 2 to 10 organic conductive tracks.

According to one embodiment, the conductive channel comprises or consists of multiple organic conductive tracks, preferably parallel to each other.

According to one embodiment, the organic conductive track is straight.

According to one embodiment, each organic conductive track is perpendicular to the longitudinal axis of the gate electrode.

According to one embodiment, each organic conductive track is parallel to the longitudinal axis of the gate electrode.

According to one embodiment, the organic conductive track is a polymer selected from polythiophenes, polypyrroles, polyanilines, polyisothianaphtalenes, polyphenylene vinylenes, polystyrenes and copolymers thereof; preferably selected from polythiophenes, polystyrenes and copolymers thereof; more preferably is poly(3,4-ethylenedioxythiophene) poly(styrene sulfonate) (PEDOT:PSS).

According to one embodiment, the organic conductive channel at least partially covers the source and the drain.

According to one embodiment, the organic electrochemical transistor further comprises a dielectric layer.

According to one embodiment, the organic electrochemical transistor further comprises at least one metallic track.

According to one embodiment, the metallic track is manufactured from metallic nanoparticles or metallic colloids, preferably selected from silver (Ag), gold (Au) and platinum (Pt). According to one embodiment, the metallic track comprises silver (Ag), gold (Au) and/or platinum (Pt).

The invention also relates to a method of manufacturing the organic electrochemical transistor according to any embodiment listed above, wherein the conductive channel is manufactured on the substrate by an additive manufacturing technique, preferably by inkjet printing.

This invention thus relates to a biosensor comprising the organic electrochemical transistor of the invention.

### Definitions

In the present invention, the following terms have the following meanings:
“About” when placed before a figure, means plus or minus 10% of the figure.
“Additive manufacturing” or “3D-printing”: refers to any process for manufacturing three-dimensional solid objects from a digital file.
“Biosensor”: refers to an analytical device which converts a biological response into an electrical signal.
“Contact surface” or “S_{contact}”: refers to the surface of one organic conductive track of the channel of an OECT, said surface being in contact with an electrolyte. According to one embodiment, the contact surface S_{contact} refers to the outer surface of the volume occupied by the printed pattern used to form the conductive track of the channel and having been deposited on the substrate of the OECT; preferably the contact surface S_{contact} is the outer surface of the hemi-cylinder, the parallelepiped rectangle, trapezoidal or any volume printed using the printing ink to form the conductive track of the channel and having been deposited on the substrate of the OECT. According to one embodiment, the printed volume using the printing ink to form the conductive track of the channel include heterogeneous volume and any volume having much more matter to its extremities than in its center. According to one embodiment, the contact surface S_{contact} refers to the outer surface of the volume occupied by the printed pattern used to form the conductive track of the channel and having been deposited on the substrate of the OECT; said conductive track of the channel 51 being characterized by a ratio r of the width w by the height h of the conductive track 51 ranging from 1 to 200.
According to one embodiment, the contact surface does not include the internal surface of porous conductive material deposited on the substrate of the OECT for manufacturing the conductive channel.
“Drain” or “Drain electrode”: refers to one of the three electrodes of an OECT as defined below.
“Gate” or “Gate electrode”: refers to one of the three electrodes of an OECT as defined below.
“Organic electrochemical transistor” or “Organic Charge Modulated Transistor” or “OECT”: refers to a device comprising three electrodes: (1) the source or source electrode, (2) the drain or drain electrode, and (3) the gate or gate electrode. In an OECT, the source and drain electrodes are connected by a conductive polymer which acts as a channel; and the channel and the gate electrode are separated by an electrolyte which acts as gate dielectric.
“Polymer”: refers to a material comprising macromolecular chains, each chain resulting from the multiple repetition of at least one repeating unit.
“Polythiophenes”: refers to a macromolecular chain having a thiophene as repeating unit, thiophene being a sulfur heterocycle. More precisely, the term “polythiophenes” refers to macromolecular chains resulting from the polymerization of thiophene and/or of its derivatives such as substituted thiophene (for example, alkylthiophenes, halogenated thiophenes, poly(ethylenedioxythiophene) (PEDOT)).
“Projected surface” or “S_{projected}”: refers to the surface of one organic conductive track of the channel of an OECT, said surface being in contact with the support of the OECT.
“Source” or “Source electrode”: refers to one of the three electrodes of an OECT as defined above.

### DETAILED DESCRIPTION

### Electrochemical Transistor 100

This invention relates to an electrochemical device 100, preferably an electrochemical transistor, more preferably an organic electrochemical transistor (OECT).

According to one embodiment, the electrochemical transistor 100 comprises three electrodes: the source 2, the drain 3 and the gate electrode 4. According to one embodiment, the electrochemical transistor 100 further comprises a substrate 1 on which are located the source 2 and the drain 3, preferably the source 2 is located on one of the end of the substrate 1 and the drain 3 is located to the other end of the substrate 1. According to one embodiment, the electrochemical transistor 100 further comprises an electrolyte 6. According to one embodiment, the substrate 1 is larger than the electrochemical transistor 100.

According to one embodiment, the transconductance gₘ of the electrochemical transistor ranges from 0 to 0.1 A/V; preferably ranges from 0.01 to 0.08 A/V, from 0.02 to 0.08 A/V, from 0.03 to 0.08 A/V, from 0.04 to 0.08 A/V, from 0.05 to 0.08 A/V, from 0.06 to 0.08 A/V, or from 0.07 to 0.08 A/V. According to one embodiment, the transconductance gₘ of the electrochemical transistor is about 0.01; 0.02; 0.03; 0.04; 0.05; 0.06; 0.07 or 0.08 A/V. According to one embodiment, the transconductance gₘ of the electrochemical transistor ranges from more than 0 to 0.08 A/V, preferably from 0.01 to 0.07 A/V, from 0.01 to 0.06 A/V, from 0.01 to 0.07 A/V, from 0.01 to 0.05 A/V, from 0.01 to 0.04 A/V, from 0.01 to 0.03 A/V or from 0.01 to 0.02 A/V.

According to one embodiment, the maximum drain-source voltage (VDS) of the electrochemical transistor ranges from 0 to −10 V, preferably from 0 to −2V, more preferably from 0 to −1V. According to one embodiment, the maximum drain-source voltage (VDS) of the electrochemical transistor in an aqueous media, ranges from 0 to −10 V, preferably from 0 to −2V, more preferably from 0 to −1V. According to one embodiment, the maximum drain-source voltage (VDS) of the electrochemical transistor is about 0, −1, −2, −3, −4, −5, −6, −7, −8, −9 or −10V.

### Substrate 1

According to one embodiment, the substrate is selected from any suitable material well-known by the skilled artisan. According to one embodiment, the substrate comprises or is made of polymer, preferably selected from polyesters and polyimides, more preferably polyethylene terephtalate (PET), poly(ethylene naphtalate) (PEN) and/or Kapton HN®.

According to one embodiment, the substrate has a length ranging from more than 0 to 20 mm, preferably from 1 to 10 mm, more preferably is about 5 mm. According to one embodiment, the substrate has a length is about 1, 2, 3, 4, 5, 6, 7, 8, 9, 10, 11, 12, 13, 14, 15, 16, 17, 18, 19 or 20 mm.

According to one embodiment, the substrate has a width ranging from more than 0 to 5 mm, preferably ranging from 0.1 to 3 mm, more preferably is about 0.5 mm.

According to one embodiment, the substrate has a width of about 0.1 mm; 0.2 mm; 0.3 mm; 0.4 mm; 0.5 mm; 0.6 mm; 0.7 mm; 0.8 mm; 0.9 mm or 1 mm. According to one embodiment, the substrate has a width of about 1 mm, 2 mm, 3 mm, 4 mm or 5 mm.

According to one embodiment, the substrate comprises one or more conductive tracks 11. According to one embodiment, the conductive track 11 of the substrate is manufactured from metallic colloids or metallic nanoparticles. According to one embodiment, the conductive track 11 of the substrate is metallic and the metal is preferably selected from transition metals, more preferably from gold, silver or platinum.

### Conductive Channel 5

According to one embodiment, the electrochemical transistor 100 further comprises a conductive channel 5. According to one embodiment, the conductive channel 5 is located on the substrate 1. According to one embodiment, the conductive channel 5 comprises or consists of at least one organic conductive track 51.

In the invention, an organic conductive track is a material in which electric conductivity is supported by charge transport from various sites on organic molecules, especially polymers. Conductivity of the material results from addition of contribution of all organic molecules, in a more or less organized way, with material dimensions at least in the micrometer range (i.e. macroscopic for material science). Accordingly, a single organic molecule or a molecular aggregate (i.e. microscopic for material science) is not considered as an organic conductive track.

According to one embodiment, the conductive channel 5 is located on the substrate 1 and contacting on one of its ends to the source 2 and on its other end to the drain 3.

According to one embodiment, the organic conductive track 51 comprises or consists of a dense or non-porous organic compound. According to one embodiment, the organic conductive track 51 comprises or consists of a porous organic compound.

According to one embodiment, the organic conductive track 51 comprises or is made of a polymer, electrically doped or not, preferably a conductive or semi-conductive polymer, more preferably selected from polythiophenes, polypyrroles, polyanilines, polyisothianaphtalenes, polyphenylene vinylenes, polystyrenes and copolymers thereof; preferably selected from polythiophenes, polystyrenes and copolymers thereof; more preferably is poly(3,4-ethylenedioxythiophene) poly(styrene sulfonate) (PEDOT:PSS). According to one embodiment, the organic conductive track 51 is doped. According to one embodiment, the organic conductive track 51 is P-doped (positive doping).

According to one embodiment, the organic conductive track 51 is N-doped (negative doping).

According to one embodiment, the organic conductive track 51 is under the form of a hemi-cylinder or the like, a hemi-sphere, a cube or a rectangular parallelepiped.

According to one embodiment, the organic conductive track 51 has a length L ranging from more than 0 to 10 cm, preferably from 0.001 cm to 5 cm; more preferably from 0.01 cm to 0.1 cm. According to one embodiment, the organic conductive track 51 has a length L is about 1 cm, 2 cm, 3 cm, 4 cm, 5 cm, 6 cm, 7 cm, 8 cm, 9 cm or 10 cm.

According to one embodiment, the organic conductive track 51 has a length L ranging from more than 0 to 1 mm, preferably from 0 to 0.1 mm. According to one embodiment, the organic conductive track 51 has a length L is about 0.01 mm; 0.02 mm; 0.03 mm; 0.04 mm; 0.05 mm; 0.06 mm; 0.07 mm; 0.08 mm; 0.09 mm or 0.1 mm. According to one embodiment, the organic conductive track 51 has a length L is about 0.1 mm; 0.2 mm; 0.3 mm; 0.4 mm; 0.5 mm; 0.6 mm; 0.7 mm; 0.8 mm; 0.9 mm or 1 mm. According to one embodiment, the organic conductive track 51 has a length L of about 10 μm.

According to one embodiment, the organic conductive track 51 has a width w ranging from more than 0 to 200 μm, preferably from 1 μm to 200 μm, more preferably from 1 μm to 100 μm; more preferably from 5 μm to 50 μm, more preferably is about 10 μm or 20 μm. According to one embodiment, the organic conductive track 51 has a width w of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100 μm. In said range of width, the organic conductive track optimizes the balance between noise and miniaturization. Indeed, very thin organic conductive tracks are sensitive to electromagnetic perturbations and yield noise. On the other hand, bulky elements in OECT are difficult to integrate in miniaturized devices.

According to one embodiment, the organic conductive track 51 has a height h ranging from 0 to 100 μm, preferably from more than 0 to 60 μm, more preferably is about 55 μm. According to one embodiment, the organic conductive track 51 has a height h is about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100 μm. According to one embodiment, the organic conductive track 51 has a height h ranging from 0 to 2 μm, preferably is from more than 0 to 1 μm.

According to one embodiment, the ratio r of the width w by height h of the organic conductive track 51 ranges from 1 to 200, preferably ranges from 1 to 190, from 1 to 180, from 1 to 170, from 1 to 160, from 1 to 150, from 1 to 140, from 1 to 130, from 1 to 100, from 1 to 90, from 1 to 80, from 1 to 70, from 1 to 60, from 1 to 50, from 1 to 40, from 1 to 30, from 1 to 20, or from 1 to 10. According to one embodiment, a ratio r higher than 1 allows increased penetration of the ions of the electrolyte 6 through the organic conductive track 51. According to one embodiment, a ratio r higher than 1 allows extinction of the electrochemical transistor 100 to lower gate potentials. According to one embodiment, a ratio r higher than 1 allows a decreasing of the gate potential from more than 0 mV to 150 mV, preferably from 50 to 100 mV, preferably from 100 to 200 mV, compared to conventional electrochemical transistor. In the present invention, the expression “conventional electrochemical transistor” means an electrochemical transistor that has not the technical features of the present invention, especially that is not characterized by a ratio R between the contact surface S_{contact} and the projected surface S_{projected} significantly higher than 1.

According to one embodiment, a ratio r higher than 1 allows decreasing the response time of the electrochemical transistor of the invention, by a factor of 2.

According to one embodiment, the gate potential in the invention is decreased from more than 0% to 100%, preferably from 1% to 100%, from 10% to 100%, from 20% to 100%, from 30% to 100%, from 40% to 100%, from 50% to 100%, from 60% to 100%, from 70% to 100%, from 80% to 100% or from 90% to 100%, compared to conventional electrochemical transistor. According to one embodiment, the gate potential in the invention is decreased from more than 0% to 90%, preferably from more than 0% to 80%, from more than 0% to 70%, from more than 0% to 60%, from more than 0% to 50%, from more than 0% to 40%, from more than 0% to 30%, from more than 0% to 20%, compared to conventional electrochemical transistor. According to one embodiment, the gate potential in the invention is decreased of about 25% compared to conventional electrochemical transistor.

According to one embodiment, the organic conductive track 51 is characterized by a contact surface (S_{contact}) corresponding to the surface of the organic conductive track 51 in contact with an electrolyte solution 6.

According to one embodiment, the organic conductive track 51 is characterized by a projected surface (S_{projected}) corresponding to the surface of the organic conductive track 51 in contact with the substrate 1. According to one embodiment, the contact surface S_{projected} ranges from 0 cm² to 0.5 cm², preferably from 10⁻⁴ cm² to 0.05 cm², more preferably from 10⁻⁴ cm² to 0.02 cm². In said range of projected surface, the balance between signal and miniaturization is improved. Indeed, signal intensity increases with increase of projected surface. On the other hand, large elements in OECT are difficult to integrate in miniaturized devices.

According to one embodiment, the organic conductive track 51 is characterized by a ratio R between the contact surface S_{contact} and the projected surface S_{projected} higher than 1. According to one embodiment, the ratio R ranges from 1 to 4, preferably is about 1, 2, 3 or 4.

According to one embodiment, the number of organic conductive tracks 51 depends on the resolution and/or the dimensions of the electrochemical transistor 100. According to one embodiment, the conductive channel 5 comprises or consists of at least two organic conductive tracks 51, preferably from 2 to 50 organic conductive tracks, more preferably from 2 to 10 organic conductive tracks. According to one embodiment, the conductive channel 5 comprises or consists of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49 or 50 organic conductive tracks.

According to one embodiment, the conductive channel 5 comprises or consists of multiple organic conductive tracks 51. According to an embodiment, each of said organic conductive tracks 51 has a width w ranging from more than 0 to 200 μm, preferably from 1 μm to 200 μm, more preferably from 1 μm to 100 μm; more preferably from 5 μm to 50 μm, more preferably is about 10 μm or 20 μm. According to an embodiment, said multiple organic conductive tracks 51 are parallel to each other. According to one embodiment, the conductive channel 5 comprises or consists of multiple parallel straight organic conductive tracks 51. According to one embodiment, the conductive channel 5 comprises or consists of multiple parallel curved organic conductive tracks 51. According to one embodiment, the conductive channel 5 is straight. According to one embodiment, the conductive channel 5 comprises at least one curvature. According to one embodiment, the conductive channel 5 comprises multiple curvatures.

According to one embodiment, the conductive channel 5 comprises or consists of multiple interdigital organic conductive tracks 51. Advantageously, interdigital organic conductive tracks 51 permits limiting the resistance of the conductive channel 5 and/or increasing the maximum electrical current intensity of the conductive channel 5.

Advantageously, interdigital organic conductive tracks 51 allows increasing the dimensions of the conductive channel 5 while keeping a geometrical surface of the electrochemical transistor lower than a conductive channel 5 having no interdigital organic conductive tracks 51.

According to one embodiment, each organic conductive track 51 is perpendicular to the longitudinal axis of the gate electrode 4. According to one embodiment, each organic conductive track 51 is parallel to the longitudinal axis of the gate electrode 4.

According to one embodiment, the conductive channel 5 is made by an additive manufacturing technique, 2D printing technique and/or 3D printing technique. According to one embodiment, at least one organic conductive track 51 is made by an additive manufacturing technique, 2D printing technique and/or 3D printing technique.

According to one embodiment, the conductive channel 5 at least partially covers the source 2 and the drain 3. Advantageously, the covering of the source 2 and the drain 3 with the conductive channel 5 permits contacting the metallic tracks and the conductive polymer. According to one embodiment, the conductive channel 5 totally covers the source 2 and the drain 3. According to one embodiment, the conductive channel 5 covers from more than 0% to 100% of the source 2, preferably from 5% to 100%, from 10% to 100%, from 15% to 100%, from 20% to 100%, from 25% to 100%, from 30% to 100%, from 35% to 100%, from 40% to 100%, from 45% to 100%, from 50% to 100%, from 55% to 100%, from 60% to 100%, from 65% to 100%, from 70% to 100%, from 75% to 100%, from 80% to 100%, from 85% to 100%, from 90% to 100%, or from 95% to 100% of the source 2. According to one embodiment, the conductive channel 5 covers from more than 0% to 90% of the source 2, preferably from more than 0% to 95%, from more than 0% to 90%, from more than 0% to 85%, from more than 0% to 80%, from more than 0% to 75%, from more than 0% to 70%, from more than 0% to 65%, from more than 0% to 60%, from more than 0% to 55%, from more than 0% to 50%, from more than 0% to 45%, from more than 0% to 40%, from more than 0% to 35%, from more than 0% to 30%, from more than 0% to 25%, from more than 0% to 20%, from more than 0% to 15%, from more than 0% to 10%, or from more than 0% to 5% of the source 2.

According to one embodiment, the conductive channel 5 covers from more than 0% to 100% of the drain 3, preferably from 5% to 100%, from 10% to 100%, from 15% to 100%, from 20% to 100%, from 25% to 100%, from 30% to 100%, from 35% to 100%, from 40% to 100%, from 45% to 100%, from 50% to 100%, from 55% to 100%, from 60% to 100%, from 65% to 100%, from 70% to 100%, from 75% to 100%, from 80% to 100%, from 85% to 100%, from 90% to 100%, or from 95% to 100% of the drain 3. According to one embodiment, the conductive channel 5 covers from more than 0% to 90% of the drain 3, preferably from more than 0% to 95%, from more than 0% to 90%, from more than 0% to 85%, from more than 0% to 80%, from more than 0% to 75%, from more than 0% to 70%, from more than 0% to 65%, from more than 0% to 60%, from more than 0% to 55%, from more than 0% to 50%, from more than 0% to 45%, from more than 0% to 40%, from more than 0% to 35%, from more than 0% to 30%, from more than 0% to 25%, from more than 0% to 20%, from more than 0% to 15%, from more than 0% to 10%, or from more than 0% to 5% of the drain 3.

### Source 2

According to one embodiment, the source 2 is manufactured by an additive manufacturing technique or by 2D- or 3D-printing, preferably by ink-jet printing. According to one embodiment, the source 2 may be any source well-known by the skilled artisan.

### Drain 3

According to one embodiment, the drain 3 is manufactured by an additive manufacturing technique or by 2D- or 3D-printing, preferably by ink-jet printing. According to one embodiment, the drain 3 may be any source well-known by the skilled artisan.

According to one embodiment, the maximum drain voltage (VDS) of the electrochemical transistor depends on the electrolyte; said electrolyte being either a solid electrolyte such as for example hydrogels, or an electrolytic solution. According to one embodiment, the maximum drain voltage (VDS) of the electrochemical transistor is about −2V. According to one embodiment, the maximum drain voltage (VDS) of the electrochemical transistor in an aqueous solution is about −2V.

### Gate Electrode 4

According to one embodiment, the gate electrode 4 is manufactured by an additive manufacturing technique or by 2D/3D printing, preferably by ink-jet printing.

According to one embodiment, the gate electrode 4 comprises or is made of a conductive material, preferably selected from conductive or semi-conductive polymers, metals, carbon and conductive allotropic carbons such as carbon nanotubes, graphite or graphene for example.

According to one embodiment, the gate electrode 4 comprises or is made of a conductive or semi-conductive polymer selected from polythiophenes, polypyrroles, polyanilines, polyisothianaphtalenes, polyphenylene vinylenes, polystyrenes and copolymers thereof; preferably selected from polythiophenes, polystyrenes and copolymers thereof; more preferably is poly(3,4-ethylenedioxythiophene) poly(styrene sulfonate) (PEDOT:PSS).

According to one embodiment, the gate electrode 4 comprises or consists of multiple conductive tracks 41.

According to one embodiment, the conductive tracks 41 of the gate electrode are parallel to the organic conductive tracks 51 of the conductive channel 5. According to one embodiment, the conductive tracks 41 of the gate electrode are perpendicular to the organic conductive tracks 51 of the conductive channel 5.

According to one embodiment, the conductive track 41 of the gate electrode is under the form of a hemi-cylinder or the like, a hemi-sphere, a cube or a rectangular parallelepiped.

According to one embodiment, the conductive track 41 of the gate electrode has a length L′ ranging from more than 0 to 10 cm, preferably from 0.001 cm to 5 cm; more preferably from 0.01 cm to 0.1 cm. According to one embodiment, the conductive track 41 has a length L′ is about 1 cm, 2 cm, 3 cm, 4 cm, 5 cm, 6 cm, 7 cm, 8 cm, 9 cm or 10 cm. According to one embodiment, the conductive track 41 has a length L′ ranging from more than 0 to 1 mm, preferably from 0 to 0.1 mm. According to one embodiment, the conductive track 41 has a length L′ is about 0.01 mm; 0.02 mm; 0.03 mm; 0.04 mm; 0.05 mm; 0.06 mm; 0.07 mm; 0.08 mm; 0.09 mm or 0.1 mm. According to one embodiment, the conductive track 41 has a length L′ is about 0.1 mm; 0.2 mm; 0.3 mm; 0.4 mm; 0.5 mm; 0.6 mm; 0.7 mm; 0.8 mm; 0.9 mm or 1 mm. According to one embodiment, the conductive track 41 has a length L′ of about 10 μm.

According to one embodiment, the conductive track 41 of the gate electrode has a width w′ ranging from more than 0 to 200 μm, preferably from 1 μm to 100 μm; more preferably from 5 μm to 50 μm, more preferably is about 10 μm or 20 μm. According to one embodiment, the conductive track 41 has a width w′ of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100 μm.

According to one embodiment, the conductive track 41 of the gate electrode has a height h′ ranging from 0 to 200 μm, preferably from more than 0 to 100 μm, more preferably is about 55 μm. According to one embodiment, the conductive track 41 has a height h′ is about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100 μm.

According to one embodiment, the maximum gate voltage (VGS) of the electrochemical transistor depends on the electrolyte; said electrolyte being either a solid electrolyte such as for example hydrogels, or an electrolytic solution. According to one embodiment, the maximum gate voltage (VGS) of the electrochemical transistor is about +5V, preferably is about +2V, +3V, +4V or +5V, more preferably is about +2V. According to one embodiment, the maximum gate voltage (VGS) of the electrochemical transistor in an aqueous solution, is about +5V, preferably is about +2V, +3V, +4V or +5V, more preferably is about +2V.

### Electrolyte 6

According to one embodiment, the electrolytic solution is a buffer, preferably a phosphate-buffered saline (PBS). According to one embodiment, the buffer may comprise sodium perchlorate (NaClO₄) or tetrabutylammonium chloride (TBACl).

According to one embodiment, the electrolyte comprises a liquid, preferably a polar liquid such as for example water, acetonitrile or ionic liquids.

### Dielectric Layer 7

According to one embodiment, the electrochemical transistor further comprises a dielectric layer 7.

According to one embodiment, the dielectric layer 7 comprises or consist of varnish. According to one embodiment, any dielectric layer well-known by the skilled artisan may be used in the present invention.

### Process

The invention also relates to a process for providing the electrochemical transistor of the invention as defined above. According to one embodiment, the process comprises at least one step of 2D- or 3D-printing, preferably ink-jet printing.

According to one embodiment, the process for providing the electrochemical transistor of the invention comprises 2D- or 3D-printing on a substrate, a conductive channel between a source and a drain located on said substrate.

According to one embodiment, the process of the invention further comprises thermal treatment of the substrate on which has(have) been printed one or more organic conductive tracks, said tracks being either organic conductive tracks of the conductive channel 5, conductive tracks of the gate 4 or any conductive tracks 11 used as electrical contacts in the electrochemical transistor 100.

According to one embodiment, 2D/3D printing, especially ink-jet printing, is implemented at a cartridge temperature ranging from more than 0° C. to 300° C. According to one embodiment, 2D/3D printing, especially ink-jet printing, is implemented at a cartridge temperature of about 10° C., 20° C., 30° C., 40° C., 50° C., 60° C., 70° C., 80° C., 90° C., 100° C., 110° C., 120° C., 130° C., 140° C., 150° C., 160° C., 170° C., 180° C., 190° C., 200° C., 210° C., 220° C., 230° C., 240° C., 250° C., 260° C., 270° C., 280° C., 290° C. or 300° C.

According to one embodiment, 2D/3D printing, especially ink-jet printing, is implemented at a plateau temperature ranging from more than 0° C. to 200° C. According to one embodiment, 2D/3D printing, especially ink-jet printing, is implemented at a plateau temperature of about 10° C., 20° C., 30° C., 40° C., 50° C., 60° C., 70° C., 80° C., 90° C., 100° C., 110° C., 120° C., 130° C., 140° C., 150° C., 160° C., 170° C., 180° C., 190° C. or 200° C.

According to one embodiment, 2D/3D printing, especially ink-jet printing, is implemented at atmospheric pressure.

According to one embodiment, 3D printing of a conductive channel on a substrate is achieved by using a conductive or semi-conductive polymer ink, preferably selected from polythiophenes, polypyrroles, polyanilines, polyisothianaphtalenes, polyphenylene vinylenes, polystyrenes and copolymers thereof; preferably selected from polythiophenes, polystyrenes and copolymers thereof; more preferably is poly(3,4-ethylenedioxythiophene) poly(styrene sulfonate) (PEDOT:PSS). According to one embodiment, the polymer ink may be doped or not. According to one embodiment, the polymer ink is doped by a positive doping (i.e. providing electrical holes in the polymer). According to one embodiment, the polymer ink is doped by a negative doping (i.e. providing excess of electrons in the polymer).

According to one embodiment, the process of the invention comprises or consists of:
ink-jet printing a conductive channel on a substrate;
ink-jet printing a gate; and
thermal treating said printed conductive channel and gate.

According to one embodiment, the process of the invention further comprises adding a dielectric layer.

### Uses

The invention also relates to the use of the electrochemical transistor of the invention, preferably as a component in electronic devices such as for example in sensors.

The invention also relates to a biosensor comprising the electrochemical transistor of the invention.

### BRIEF DESCRIPTION OF THE DRAWINGS

The detailed description will be better understood when read in conjunction with the drawings. For the purpose of illustrating, the electrochemical transistor is shown in the preferred embodiments. It should be understood, however that the application is not limited to the precise arrangements, structures, features, embodiments, and aspect shown. The drawings are not drawn to scale and are not intended to limit the scope of the claims to the embodiments depicted. Accordingly it should be understood that where features mentioned in the appended claims are followed by reference signs, such signs are included solely for the purpose of enhancing the intelligibility of the claims and are in no way limiting on the scope of the claims.

FIG. 1 is a perspective side view of an organic conductive track 51 of the electrochemical transistor 100 of the invention. The organic conductive track 51 is characterized by its length L, its width w, its height h, a contact surface S_{contact} and a projected surface S_{projected}. According to the invention, the organic conductive track 51 is obtained by ink-jet printing a conductive polymer ink under the form of a full hemi-cylinder, so that the contact surface S_{contact} is higher than the projected surface S_{projected}. According to one embodiment, the organic conductive track 51 is obtained by ink-jet printing a conductive polymer ink under the form of a full hemi-cylinder having a width w higher than its height h.

FIG. 2 is a scheme (top view) of the electrochemical transistor 100 of the invention including metallic tracks 11 and a conductive channel 5 comprising interdigital multiple straight and parallel organic conductive tracks 51 arranged on a substrate 1. Above the substrate 1 is arranged the gate electrode 4 configured to have its longitudinal axis parallel to the organic conductive tracks 51.

FIGS. 3 to 8 show schemes of alternative configurations of the electrochemical transistor 100 of the invention. In FIG. 3, the organic conductive tracks 51 are perpendicular to the longitudinal axis of the gate 4; said organic conductive tracks 51 and said gate 4 being on the same side of the OECT, whereas in FIG. 4 they are on opposite sides.

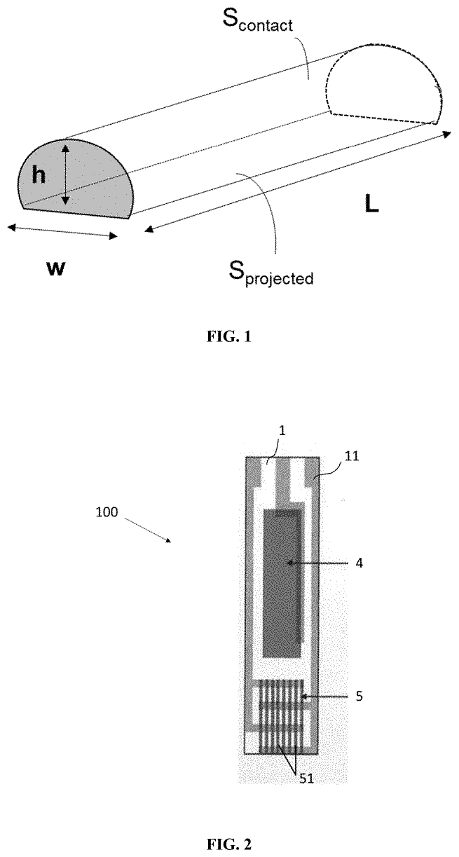

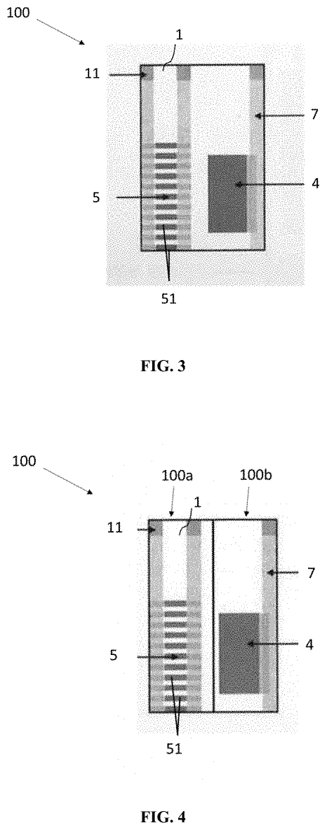

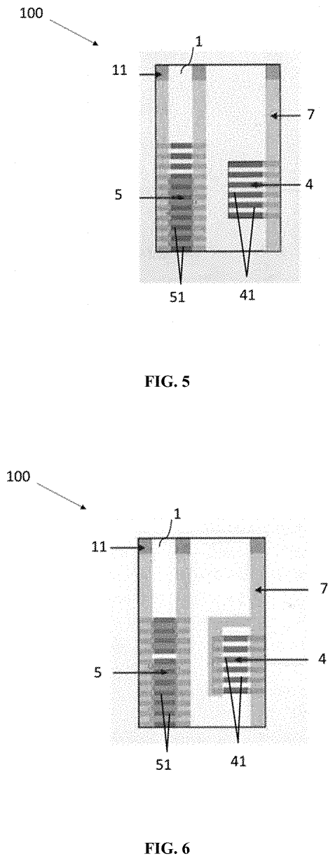

In FIG. 5, the gate 4 comprises multiple straight and parallel conductive tracks 41 which are parallel to the multiple straight and parallel organic conductive tracks 51 of the conductive channel 5. FIG. 6 show similar scheme of FIG. 5 except that in FIG. 6 the dielectric layer 7 comprises a double contact with the gate 4, at each ends of the conductive tracks 41 of said gate 4.

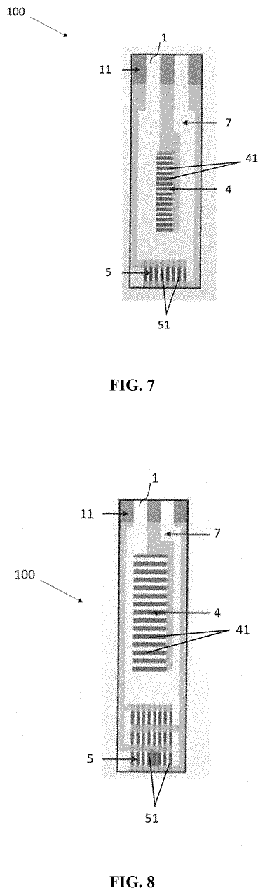

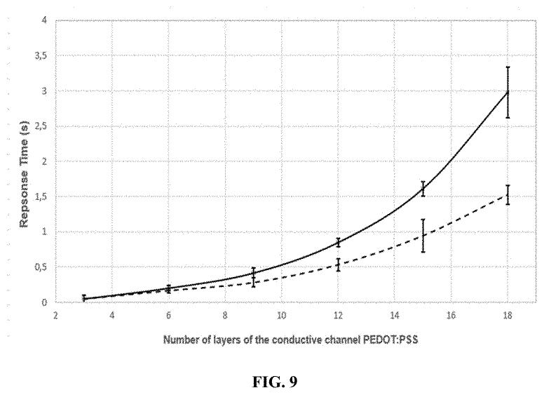

In FIGS. 7 and 8, the gate 4 under the form of a multiple straight and parallel conductive tracks 41, is located above the substrate 1 on which are arranged organic conductive tracks 51 of the conductive channel 5, said organic conductive tracks 51 being under the form of a multiple straight and parallel tracks and being perpendicular to the conductive tracks 41 of the gate 4. In FIG. 8 contrary to FIG. 7, the organic conductive tracks 51 of the conductive channel 5 are interdigital.

FIG. 9 is a graph showing the response time as a function of the number of layers of the conductive channel PEDOT-PSS for achieving 90% channel extinction depending on whether the channel is square (full line) or is multiline as in the present invention (dotted line).

### REFERENCES

100—Organic electrochemical transistor;
100a—Front face of the electrochemical transistor;
100b—Back face of the electrochemical transistor;
1—Substrate;
11—Metallic track;
2—Source;
3—Drain;
4—Gate electrode;
41—Conductive track of the gate electrode;
5—Conductive channel;
51—Organic conductive track;
6—Electrolyte;
7—Dielectric layer;
L—Length of the conductive track of the conductive channel;
w—Width of the conductive track of the conductive channel;
h—Height of the conductive track of the conductive channel;
S—Track section of the conductive track of the conductive channel;
L′—Length of the conductive track of the gate electrode;
w′—Width of the conductive track of the gate electrode;
h′—Height of the conductive track of the gate electrode.

1-14. (canceled)

15. An organic electrochemical transistor comprising:
a substrate on which are located a source and a drain;
a gate electrode; and
a conductive channel located on the substrate and contacting on one of its ends the source and on its other end the drain; said conductive channel comprising or consisting of at least one organic conductive track;
wherein said at least one organic conductive track has:
a contact surface S_{contact} corresponding to the contact surface of the at least one organic conductive track with an electrolyte solution;
a projected surface S_{projected} corresponding to the contact surface of the at least one organic conductive track with the substrate; said projected surface S_{projected} ranging from 10⁻⁴ cm² to 0.05 cm² or said projected surface S_{projected} being the contact surface of multiple organic conductive tracks, each of said multiple organic conductive tracks having a width w ranging from 1 μm to 200 μm; and
a ratio R between the contact surface S_{contact} and the projected surface S_{projected} higher than 1.

16. The organic electrochemical transistor according to claim 15, comprising a ratio r of the width w by height h of the at least one organic conductive track ranges from 1 to 200.

17. The organic electrochemical transistor according to claim 15, wherein the conductive channel comprises or consists of at least two organic conductive tracks.

18. The organic electrochemical transistor according to claim 15, wherein the conductive channel comprises or consists of multiple organic conductive tracks.

19. The organic electrochemical transistor according to claim 15, wherein the organic conductive track is straight.

20. The organic electrochemical transistor according to claim 15, wherein each organic conductive track is perpendicular to the longitudinal axis of the gate electrode.

21. The organic electrochemical transistor according to claim 15, wherein each organic conductive track is parallel to the longitudinal axis of the gate electrode.

22. The organic electrochemical transistor according to claim 15, wherein the organic conductive track is a polymer selected from polythiophenes, polypyrroles, polyanilines, polyisothianaphtalenes, polyphenylene vinylenes, polystyrenes and copolymers thereof.

23. The organic electrochemical transistor according to claim 15, wherein the organic conductive channel at least partially covers the source and the drain.

24. The organic electrochemical transistor according to claim 15, further comprises a dielectric layer.

25. The organic electrochemical transistor according to claim 15, further comprising at least one metallic track.

26. The organic electrochemical transistor according to claim 25, wherein the metallic track is manufactured from metallic nanoparticles or metallic colloids.

27. A method of manufacturing the organic electrochemical transistor according to claim 15, wherein the conductive channel is manufactured on the substrate by an additive manufacturing technique.

28. A biosensor comprising the organic electrochemical transistor according claim 15.
